(19) United States
(12) Patent Application Publication
(10) Pub. No.: US 2016/0014879 A1
(43) Pub. Date: Jan. 14, 2016

(54) A PRINTED CIRCUIT BOARD (PCB) STRUCTURE

(71) Applicant: HANGZHOU H3C TECHNOLOGIES CO., LTD., Zhejiang (CN)

(72) Inventor: Yi LI, Beijing (CN)

(21) Appl. No.: 14/769,301

(22) PCT Filed: Nov. 18, 2013
(86) PCT No.: PCT/CN2013/087291

§ 371 Date: Aug. 20, 2015

(30) Foreign Application Priority Data
Mar. 7, 2013 (CN) 201320104032.7

(51) Int. Cl. H05K 1/02; H05K 1/18; H05K 1/11

(52) U.S. Cl. CPC H05K 1/0206; H05K 1/115; H05K 1/18

(57) ABSTRACT

According to an example, a printed circuit board (PCB) structure may include a substrate having a first surface and a second surface. The PCB structure may also include a heat radiating groove formed on the first surface of the substrate.

### BACKGROUND

Components on printed circuit boards (PCBs) are being developed to consume ever-increasing amounts of power in performing tasks of greater complexity. One result of this increase in power consumption is that the PCB components are generating increasing amounts of heat, which should be dissipated quickly in order to extend the useful working lives of PCB components.

### BRIEF DESCRIPTION OF THE DRAWINGS

Features of the present disclosure are illustrated by way of example and not limited in the following figure(s), in which like numerals indicate like elements, in which:

FIG. 1A illustrates a schematic sectional view of a PCB structure according to an example of the present disclosure.

FIG. 1B illustrates a schematic sectional view of a PCB structure according to another example of the present disclosure.

FIG. 1C illustrates another angle schematic sectional view of a PCB structure shown in FIG. 1B.

FIG. 2A illustrates a schematic perspective view of a PCB structure according to an example of the present disclosure.

FIG. 2B illustrates a bottom view of a PCB structure according to an example of the present disclosure.

FIG. 3 illustrates a schematic perspective view of a heat radiating groove of a PCB structure according to an example of the present disclosure.

FIG. 4 is a schematic diagram illustrating an optical connector according to an example of the present disclosure.

### DETAILED DESCRIPTION

For simplicity and illustrative purposes, the present disclosure is described by referring to examples. It will be readily apparent however, that the present disclosure may be practiced without limitation to these specific details. In other instances, some methods and structures have not been described in detail so as not to unnecessarily obscure the present disclosure. As used herein, the term “includes” means includes but not limited to, the term “including” means including but not limited to. The term “based on” means based at least in part on. In addition, the terms “a” and “an” are intended to denote at least one of a particular element.

Conventional systems generally implement one of two techniques to dissipate heat generated by PCB components mounted on a surface of a PCB structure.

A first technique seeks to improve a heat exchange ability of a PCB component. In this technique, for example, a fan is positioned near the PCB component or another assistant device, such as a heat sink, is positioned on the PCB component to increase airflow speed around the PCB component.

This first technique therefore requires that an additional heat radiating device be added to the PCB component, which typically increases the cost and complexity associated with using the PCB component. In addition, this first technique may not be applicable for small and compactly arranged components, such as a high power Light Emitting Diode (LED).

A second technique uses thermal vias that extend through a thickness of the PCB to enhance heat dissipation from the PCB component.

PCBs generally comprise one or more electrically conductive layers and a plurality of electrically insulating layers. The electrically insulating and electrically conducting layers are laid on top of each other so that each electrically conductive layer is sandwiched between a pair of electrically insulating layers. The electrically conductive layers may comprise electrically conductive tracks, pads and other electrical components which may for example be etched from a sheet of electrically conductive material, such as a copper foil. The insulating layers have low heat conductivity but the copper foil has high heat conductivity. Therefore, in the second technique, thermal vias are fabricated on pads corresponding to the PCB components, and the copper foil may be laid in the thermal vias to enhance heat dissipation from the PCB components.

However, in PCBs having high heat dissipation requirements, the second technique requires a specially-designed metal substrate PCB, so as to dissipate heat rapidly. This requirement increases the cost and complexity associated with fabricating the PCBs. In addition, the heat dissipation ability of the PCB itself cannot be greatly expanded under this technique. Moreover, with the increased thickness of the PCB, the thermal via becomes increasingly longer. However, as the thermal via becomes increasingly longer, the ability of the thermal via to dissipate heat worsens. In fact, if the power consumption of the PCB component increases beyond a certain level, a conventional PCB heat dissipation device or thermal via may be unable to adequately dissipate heat generated by the PCB component.

In contrast, disclosed herein is a PCB structure, in which, heat radiating grooves may be formed on idle positions of a surface of a PCB. In one regard, the heat radiating grooves may increase a heat dissipation area of the PCB structure and may improve the dissipation of heat from the PCB structure.

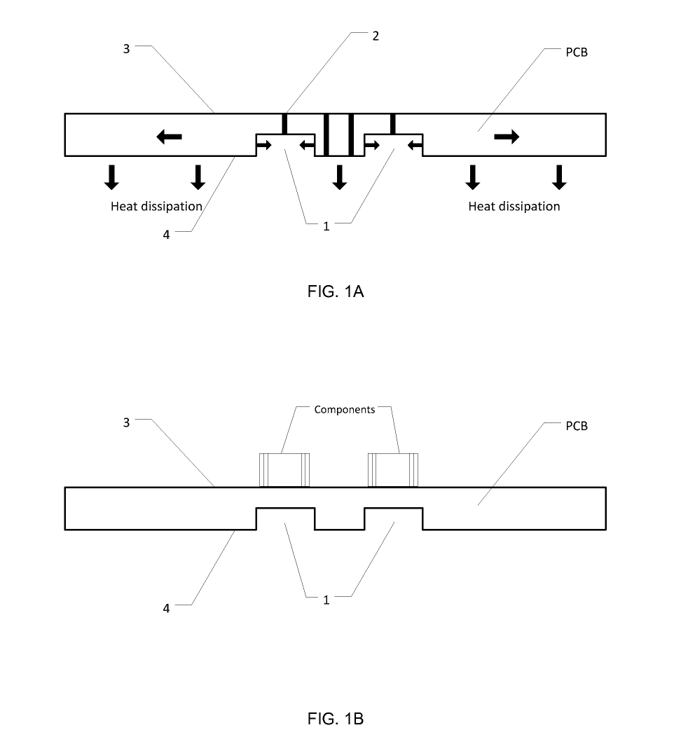

With reference first to FIG. 1A, there is shown a schematic sectional view of a PCB structure according to an example of the present disclosure. In FIG. 1A, the arrows denote heat dissipation directions. As also shown in FIG. 1A, heat radiating grooves 1 are formed into a substrate of the PCB structure. In an example, the heat radiating grooves 1 may be formed on idle positions of a surface of the PCB structure and may have a concave configuration to increase the area in which heat may be dissipated from the PCB structure. In one regard, the heat radiating grooves 1 may improve the heat dissipation ability of the PCB without requiring that additional assistant heat dissipation devices, such as fans, heat sinks, etc., be implemented. In the example of FIG. 1A the arrows inside the PCB structure indicate heat conduction and the arrows extending from the PCB surface schematically indicate radiation of heat into the surrounding atmosphere. The heat radiating grooves 1 may increase the rate of heat radiation because they increase the surface area exposed to the atmosphere.

According to an example, the heat radiating grooves 1 may be formed on a lower surface 4 of the PCB structure. In this regard, the heat radiating grooves 1 may be formed on a surface of the PCB structure that is opposite the surface 3 on which components of the PCB structure may typically be arranged. The heat radiating grooves 1 may be formed on spare positions of the PCB structure. “spare positions” are positions of the PCB structure that are not connected to electronic elements. In addition, the heat radiating grooves 1 may be positioned on the lower surface 4 of the PCB structure at locations that correspond to the positions of components on the upper surface 3 of the PCB structure, i.e., directly beneath the components, as shown in FIG. 1B.

The heat radiating grooves 1 may be formed on the lower surface 4 of the PCB structure through any suitable fabrication technique. For instance, the heat radiating grooves 1 may be formed through milling, drilling, etc., into the lower surface 4 of the PCB structure. In addition, the heat radiating grooves 1 may be formed to have various different shapes, such as a cuboid, a cylinder, an arcuate recess, etc. The heat radiating grooves 1 may be formed to have a particular configuration for different application scenarios. In addition, the heat radiating grooves 1 may be formed to have heights that extend as far into the substrate of the PCB structure as possible without substantially compromising the structural integrity of the PCB structure so as to substantially maximize the areas of the heat radiating grooves 1.

By “formed on the lower surface of the PCB structure”, it is meant that the grooves are formed in the PCB structure itself, rather than being a separate heat sink mounted on the PCB structure. For example, the PCB structure may comprise at least one conducting layer and a plurality of insulating layers between the upper and lower surfaces. The heat radiating grooves 1 may be formed in an insulating layer of the PCB structure and may have a depth which extends into the insulating layer. For example, in FIG. 1C the PCB substrate includes electrically insulating layers 10, 12 and 14 and electrically conductive layers 11 and 13 sandwiched between the electrically insulating layers. The heat radiating grooves 1 in the first surface 4 have a depth D which extends into the insulating layer 10.

According to an example, the PCB structure may be configured with at least one of the following additional features, which may further enhance heat dissipation from the PCB structure. The PCB structure may be configured with any of the following additional features before, during, or after formation of the heat radiating grooves 1.

In a first example, a thermal via may be provided on a heat radiating groove 1. As described above, the shorter the length of the thermal via through the PCB structure, the better the thermal via is at dissipating heat. Therefore, in this example, a thermal via 2 may be provided through the PCB structure between a heat radiating groove 1 and the upper surface 3 of the PCB structure, as shown in FIG. 1A. In one regard, therefore, the thermal via 2 may have a relatively shorter length as compared to thermal vias that extend between the lower surface 4 and the upper surface 3 of the PCB structure. The thermal via 2 may comprise a small hole drilled or otherwise formed in the PCB structure and may have an inner surface plated with a heat conductive material such as copper or another metal or alloy.

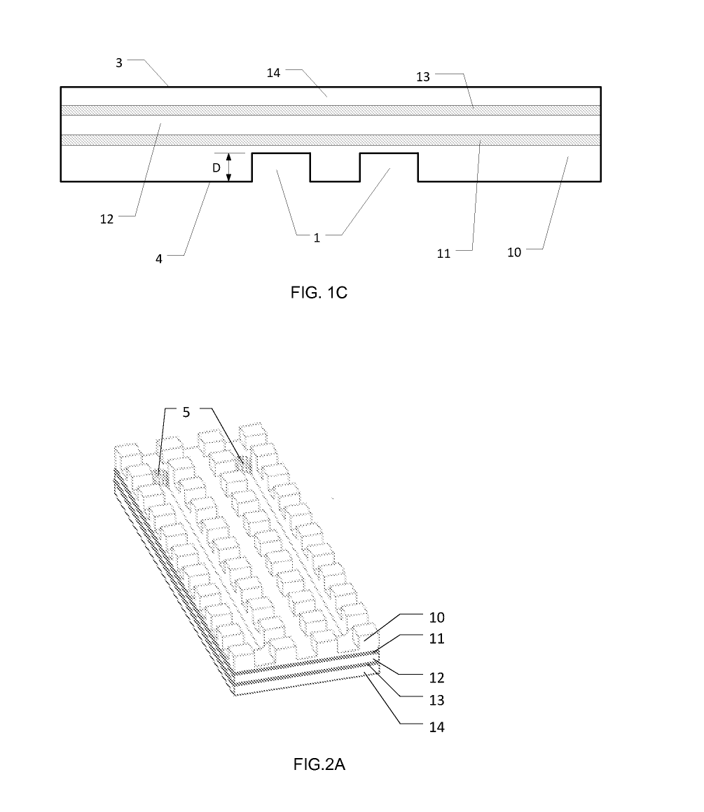

In a second example, the heat radiating grooves 1 may be interconnected. In this example, a plurality of heat radiating grooves 1 may be interconnected, as shown in FIG. 2A and FIG. 2B. The interconnection of the heat radiating grooves 1 may enhance heat dissipation from the PCB structure by reducing obstructions to the heat dissipation. In addition, the thermal vias 2 provided on the interconnected heat radiating grooves 1 discussed above may be interconnected to form a large thermals via 5, as shown in FIG. 2A and FIG. 2B. The large thermal via may comprise a hollow hole drilled or otherwise formed in the PCB structure and may have an inner surface coated with a heat conductive material such as copper or another metal or alloy. FIG. 2A and FIG. 2B show two large thermal vias 5A and 5B. The large thermal vias are located on the interconnected heat radiating grooves. More specifically, for example, as shown in FIG. 2B, the plurality of heat radiating grooves may include a first groove 1A and extending in a first direction and second and third grooves 1B, 1C extending in a second direction and intersecting with the first groove 1A. For ease of reference, the intersection of first groove 1A with second groove 1B may be referred to as the first intersection (see 1AB in FIG. 2B) and the intersection of first groove 1A with third groove 1C may be referred to as the second intersection (see 1AC in FIG. 2B). Large thermal via 5 extends along the first heat radiating groove 1A and crosses both the first and second intersections 1AB, 1AC. Thus it is elongate and has a length greater than its width. As the area of large thermal via 5A is larger than the area covered by normal thermal via 2, the large thermal via helps to increase the heat dissipation area and improve heat dissipation. FIG. 2B also shows a fourth heat radiating groove 1D extending in the same direction as first heat radiating groove 1A and intersecting with grooves 1B and 1C at intersections 1BD, 1CD. This fourth heat radiating groove 1D may also have a large thermal via 5B as shown in FIG. 2B. While in FIG. 2 the large thermal vias extend past two intersections, in other examples they may be longer and extend past more than two intersections between the heat radiating grooves.

In a third example, the surfaces of the heat radiating grooves 1 and idle positions of the lower surface 4 of the PCB structure may be provided with a heat conductive material, such as copper. In other words, after the heat radiating grooves 1 are formed on the PCB structure as discussed herein, a heat conductive material layer, such as copper, may be formed in the heat radiating grooves 1 and on the idle positions of the lower surface 4 of the PCB structure. By way of example in which the heat conductive material is copper, the heat conductive layer may be provided through electroless plating of copper onto the heat radiating grooves 1 and other sections of the lower surface 4.

According to a particular example, the heat conductive material layer covers at least 50% of the surfaces of the heat radiating grooves 1. The thickness of the heat conductive material layer may vary based upon manufacturing tolerances and may generally not be lower than about 25 micrometers. The thickness of the heat conductive material layer should be less than the depth of the groove so that a groove is still present on the first surface to increase the exposed surface area and promote heat radiation.

As may be noted from the discussion above, the PCB structure disclosed herein may have enhanced heat dissipation properties without requiring the use of an additional heat dissipation assistant device. Instead, the PCB structure disclosed herein utilizes heat radiating grooves that are formed into the thickness of the PCB structure. The PCB structured disclosed herein may be fabricated through common fabrication techniques and may thus be fabricated in a relatively simple and low cost manner, while providing enhanced heat dissipation.

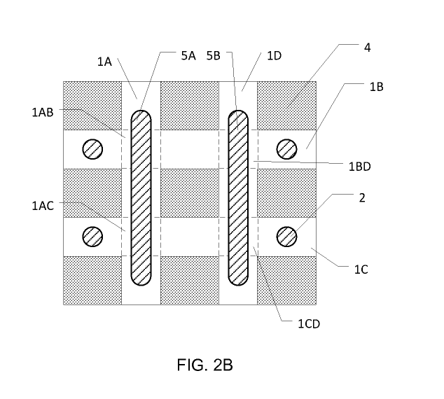

By way of particular example, in which an area that heat radiating grooves may be formed in a PCB structure is 10 mm*10 mm, an original heat dissipation area is 10*10=100 mm². In this example, 4 interconnected heat radiating grooves are formed on the surface of the PCB structure in manners as discussed above, each of which is 10 mm wide and 1.5 mm deep. The shapes of the heat radiating grooves may be as shown in FIG. 3. Thus, a total of 24 heat radiating sidewalls are formed, each of which is 2 mm*1.5 mm. A heat dissipation area of the 24 sidewalls is 24*2*1.5=72 mm². That is, compared with a conventional PCB structure, the heat dissipation area of the PCB structure in this example is greatly increased through formation of the heat radiating grooves in the PCB structure. In this example, after the heat radiating grooves are formed in the PCB structure, the heat dissipation area of the PCB structure is increased by as much as 72%.

In conventional techniques, besides increasing the costs and complexities associated with implementing an additional heat dissipation assistant device, the space occupied by the components and the additional heat dissipation assistant device is relatively larger than may be required through implementation of the PCB structure disclosed herein.

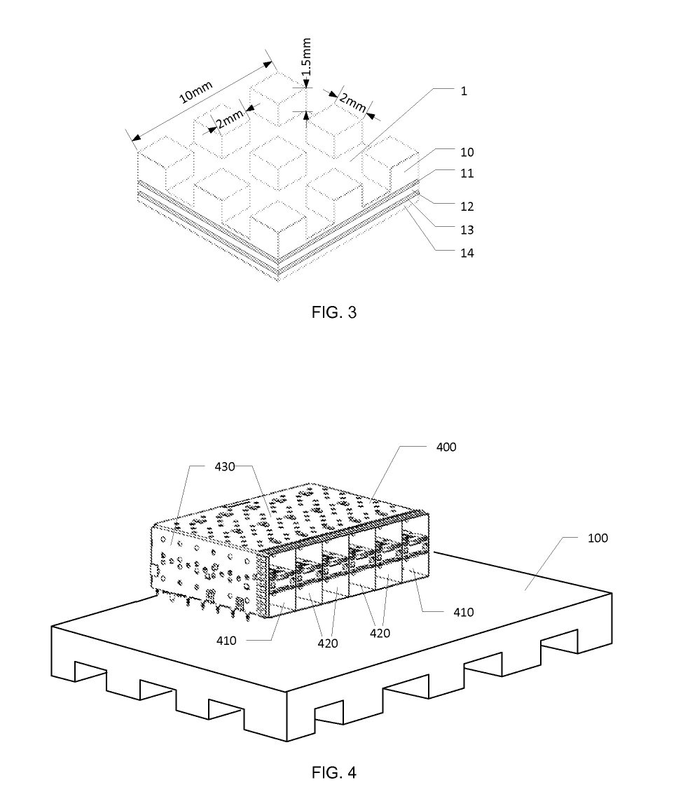

Hereinafter, an optical connector is taken as an example component on the PCB structure disclosed herein. FIG. 4 is a schematic diagram illustrating an optical connector 400 according to an example of the present disclosure. In this example, the optical connector 400 has upper optical modules and lower optical modules inserted in the optical connector 400. Heat generated by the upper optical modules may be dissipated via a metal shell 430 of the optical connector 400. In addition, heat generated by the lower optical modules that are close to edge positions (e.g., position 410 in FIG. 4) of the optical connector 400 may also be dissipated via the metal shell 430 of the optical connector 400. However, it is more difficult to dissipate heat generated by the lower optical modules in middle positions (e.g., positions 420 in FIG. 4) of the optical connector 400 because these lower optical modules may not readily access the metal shell 430 of the optical connector 400. In addition, the tops and sides of these lower optical modules may be covered and the bottoms of these lower optical modules may be in thermal contact with a connector of the PCB structure. According to an example, the PCB structure 100 connected to the lower part of such an optical connector 400 may have the PCB structure disclosed in the present disclosure. That is, the PCB structure may include heat radiating grooves on the lower surface of the PCB structure as shown, for instance, in FIGS. 1-3. In addition, the PCB structure may also include thermal vias on the heat radiating grooves. In addition, or alternatively, the heat radiating grooves in the PCB structure may be interconnected and may further include additional grooves. The PCB structure may further additionally, or alternatively, include a thermally conductive material, such as plate copper foil, on the heat radiating grooves.

What has been described and illustrated herein is an example of the disclosure along with some of its variations. The terms, descriptions and figures used herein are set forth by way of illustration. Many variations are possible within the spirit and scope of the disclosure, which is intended to be defined by the following claims and their equivalents.

1. A printed circuit board (PCB) structure, comprising:
a substrate having a first surface and a second surface;
a heat radiating groove formed on the first surface of the substrate.

2. The PCB structure of claim 1, wherein the second surface of the substrate is to receive components and wherein the first surface of the substrate is not to receive components.

3. The PCB structure of claim 1, further comprising:
a plurality of heat radiating grooves formed on the first surface of the substrate, wherein at least two of the plurality of heat radiating grooves are interconnected.

4. The PCB structure of claim 3, wherein the plurality of heat radiating grooves include a first heat radiating groove, a second heat radiating groove and a third heat radiating groove, the second heat radiating groove intersecting with the first heat radiating groove at a first intersection and the third heat radiating groove intersecting with the first heat radiating groove at a second intersection; and wherein
a thermal via is formed on the first heat radiating groove and said thermal via extends across the first and second intersections.

5. The PCB structure of claim 1, wherein an inner surface of the heat radiating groove is covered by a heat conductive material layer.

6. The PCB structure of claim 5, wherein the heat conductive material layer is a copper layer.

7. The PCB structure of claim 5, wherein the heat conductive material layer covers at least 50% of an inner surface of the heat radiating groove.

8. The PCB structure of claim 1, further comprising a thermal via extending through the substrate between the heat radiating groove and the second surface.

9. A printed circuit board (PCB) structure, comprising:
a PCB substrate having a first surface and a second surface;
the PCB substrate comprising at least one electrically conductive layer and a plurality of electrically insulating layers between the first surface and the second surface;
at least one heat radiating groove formed on the first surface of the PCB substrate and having a depth extending into an electrically insulating layer of the PCB substrate.

10. The PCB structure of claim 9, wherein one or more components are mounted on the second surface of the PCB substrate and no components are mounted on the second surface of the PCB substrate.

11. The PCB structure of claim 10, wherein the one or more components on the second surface are mounted at positions opposite a heat radiating groove on the second surface.

12. A printed circuit board (PCB) structure, comprising:
a substrate having a first surface and a second surface;
a heat radiating groove formed on the first surface of the substrate; and
an optical connector mounted on the second surface of the substrate.

13. The PCB structure of claim 12, further comprising:
a plurality of heat radiating grooves formed on the first surface of the substrate, wherein at least two of the plurality of heat radiating grooves are interconnected.

14. The PCB structure of claim 13, wherein the plurality of heat radiating grooves include a first heat radiating groove, a second heat radiating groove and a third heat radiating groove, the second heat radiating groove intersecting with the first heat radiating groove at a first intersection and the third heat radiating groove intersecting with the first heat radiating groove at a second intersection; and wherein
a thermal via is formed on the first heat radiating groove and said thermal via extends across the first and second intersections.

15. The PCB structure of claim 12, wherein an inner surface of the heat radiating groove is covered by a heat conductive material layer.
